(19) United States
(12) Patent Application Publication
(10) Pub. No.: US 2024/0107693 A1
(43) Pub. Date: Mar. 28, 2024

(54) DISPLAY APPARATUS

(71) Applicant: LG Display Co., Ltd., Seoul (KR)

(72) Inventor: Doohee CHO, Paju-si (KR)

(73) Assignee: LG Display Co., Ltd., Seoul (KR)

(21) Appl. No.: 18/371,171

(22) Filed: Sep. 21, 2023

(30) Foreign Application Priority Data
Sep. 27, 2022 (KR) 10-2022-0122269

(51) Int. Cl. H05K 5/02

(52) U.S. Cl. CPC H05K 5/0234

(57) ABSTRACT

A display apparatus includes a display panel including a back cover attached to a back surface thereof and configured to be bent or curved with a predetermined amount of elasticity; a tilting unit positioned at left and right ends of a back surface of the back cover, allowing the display panel to switch between a flat state and a curved state; a curved bar extended over the back surface of the back cover with a predetermined curvature and coupled with the tilting unit; and a support unit connected to the tilting unit to support the display panel, thereby allowing users to conveniently switch the display apparatus to a flat state to a curved state from the front of the display apparatus while in use.

### CROSS-REFERENCE TO RELATED APPLICATIONS

The present application claims the priority of Korean Patent Application No. 10-2022-0122269 filed on Sep. 27, 2022, which is hereby incorporated by reference in its entirety.

### BACKGROUND

### Field of the Disclosure

The present disclosure relates to a display apparatus that allows users to conveniently switch a display panel between a flat and curved state.

### Description of the Background

Displays have undergone a significant transition from cathode ray tube (CRT) to flat-panel displays, and since then, the main goal has been to develop larger and higher-quality displays. Meanwhile, the development of flat-panel displays has played a significant role in the success of mobile products such as smartphones, entailing the development of higher-resolution displays.

For example, flat-panel display apparatuses include liquid crystal display (LCD) apparatuses, plasma display panel (PDP) apparatuses, field emission display (FED) apparatuses, and light emitting display apparatuses, and research on these technologies is actively underway.

Recently, there has been a particular emphasis on the need for research and development of curved display products that are more appealing to consumers, in addition to addressing the technical limitations of flat-panel display apparatuses.

Along with this trend, there is a growing demand for display apparatuses with curvature, such as curved or bendable display apparatuses.

Existing curved display apparatuses have been developed in such a way either by preparing a panel and back cover having a certain curvature and combining on the back with a fixing device having the same curvature as the back cover or by combining a separate curvature adjustment device with the panel and back cover to change their curvature.

However, in the case of the structure where a fixing device with the same curvature as the panel and back cover is combined on the back of a panel and back cover, a problem arises in that jig and press processes are required to form all parts, such as the panel and back cover, into a certain curvature. In addition, once the product is completed, it may only maintain a certain fixed curvature, which poses a problem in catering to the diverse demands of consumers for changes in curvature.

Therefore, there is a need for display apparatuses capable of implementing various curvatures without being limited by manufacturing equipment or processes while catering to the diverse curvature demands of consumers.

### SUMMARY

Accordingly, the present disclosure is directed to a display apparatus that substantially obviates one or more of problems due to limitations and disadvantages described above.

More specifically, the present disclosure is to provide a display apparatus that allows users to conveniently switch between a flat state and a curved state at the front of the display apparatus only with an action of moving the weight center of the display panel while in use.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display apparatus includes a display panel including a back cover attached to a back surface thereof and configured to be bent or curved with a predetermined amount of elasticity, a tilting unit positioned at a left and right ends of a back surface of the back cover, allowing the display panel to switch between a flat state and a curved state, a curved bar extended over the back surface of the back cover with a predetermined curvature and coupled with the tilting unit, and a support unit connected to the tilting unit to support the display panel.

The curved bar extends on both sides with the same curvature with respect to a center of the back surface of the curved bar.

The back cover is provided with a magnet inducing, in response to the display panel switching from the flat state to the curved state, the attachment of the curved bar by magnetic force.

The magnet is arranged on the left and right sides of the back surface of the back cover centered on the middle of the back surface.

The back cover is provided with a handle unit positioned at the center of the back surface of the back cover being selectively engaged with the curved bar in response to the display panel being switched from the flat state to the curved state.

The handle unit comprises a weight member of a predetermined weight.

The display panel has the center of gravity moving in the direction of gravity, in response to the display panel rotating to be horizontal with respect to the tilting unit, due to the weight of the display panel and the weight of the handle unit.

The display panel is configured to bend in the direction of gravity, in response to the display panel rotating to be horizontal with respect to the tilting unit, to cause the magnet to attach to one surface of the curved bar, thereby being switched to the curved state.

The tilting unit is positioned at the center of the total vertical length of the back cover when viewed from the rear.

The tilting unit includes a tilting unit body forming the overall appearance, a groove formed on the inner upper surface and inner lower surface of the tilting unit body, facing each other and extending in a predetermined depth and length in one direction, and a tilting arm connected at one end thereof to a sliding pin, which is inserted at both ends thereof into the groove, in a rotatable manner and extends toward the rear of the tilting unit at the other end.

The sliding pin includes a round portion at the upper and lower ends thereof.

The tilting arm includes a first tilting arm rounded toward the inside of the tilting unit body and connected to the sliding pin at both ends thereof in the axial direction in an inserted manner; and a second tilting arm extending from the first tilting arm toward the rear of the tilting unit body and hinged to the curved bar and the support unit.

The curved bar includes a curved bar body forming the overall appearance, a holding portion formed at the center of the curved bar body to maintain the attachment of the handle unit, and a third tilting arm formed facing the tilting unit at the extended left and right ends of the curved bar body.

The curved bar body includes a supporting portion formed integrally therewith to support the back cover in response to the display panel being in the flat state.

The supporting portion is arranged in a symmetrical form with respect to the hording portion.

The support unit moves together with the tilting unit in response to the display panel being switched between the flat state and the curved state.

In another aspect of the present disclosure, a display apparatus includes a display panel including a back cover attached to the back surface thereof and configured to be bent or curved with a predetermined amount of elasticity, a magnet provided on the back surface of the back cover, a tilting unit positioned at a left and right ends of the back surface of the back cover, allowing the display panel to switch between a flat state and a curved state, a curved bar extended over the back surface of the back cover with a predetermined curvature and coupled with the tilting unit, an auxiliary magnet provided on one side of the curved bar to be selectively attached to or detached from the magnet, and a support unit connected to the tilting unit to support the display panel.

The curved bar extends on both sides with the same curvature with respect to the center of the back surface of the curved bar, and the auxiliary magnet has the opposite polarity to the magnet.

The aspects are advantageous in terms of improving user convenience and preventing the expensive display panel from damage by allowing the user to easily switch the display panel between a flat state and a curved state at the front of the display panel while in use.

The aspects are advantageous in terms of allowing the user to conveniently switch the display panel to a flat or curved state by utilizing the principle that the weight center of the display panel faces the direction of gravity when switching the display panel.

The aspects are advantageous in terms of reducing the weight of the support and resultantly the overall size by allowing the display panel to be switched to a flat or curved state only with a force in the direction of gravity.

The aspects are advantageous in terms of allowing the display panel to be switched to a curved state, ensuring a constant and stable curvature by utilizing a magnet and a curved bar.

The aspects are advantageous in terms of preventing plastic deformation of the components equipped in the display apparatus by modifying the structure to support the back cover of the display apparatus using a curved bar.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a perspective view of a display apparatus in a flat state according to an aspect of the present disclosure;

FIG. 2 is a perspective view of a display apparatus switching from a flat state to a curved state according to an aspect of the present disclosure;

FIG. 3 is a cross-sectional view illustrating an assembled state of a display panel and a back cover according to an aspect of the present disclosure;

FIG. 4 is a rear perspective view of a display apparatus in FIG. 1;

FIG. 5 is a partial perspective view of a handle unit and a curved bar according to an aspect of the present disclosure;

FIG. 6 is a perspective view of a display apparatus in the state of being rotated to be horizontal for switching from a flat state to a curved state;

FIG. 7 is a cross-sectional view illustrating the display panel of FIG. 6 in the state of being curved in the direction of gravity by gravity;

FIG. 8 is a perspective view of a display apparatus in a curved state according to an aspect of the present disclosure;

FIG. 9 is a rear perspective view of a display apparatus in FIG. 8;

FIG. 10 is a partial perspective view illustrating a tilting unit, a curved bar, and a support unit in a combined state thereof according to an aspect of the present disclosure;

FIGS. 11 and 12 are cross-sectional views illustrating a configuration of a tilting unit according to an aspect of the present disclosure; and

FIG. 13 is a rear perspective view of a display apparatus according to another aspect of the present disclosure.

### DETAILED DESCRIPTION

Advantages and features of the present disclosure and methods of accomplishing the same may be understood more readily by reference to the detailed description of aspects that will be made hereinafter with reference to the accompanying drawings. The present disclosure may, however, be embodied in many different forms and should not be construed as being limited to the exemplary aspects set forth herein; rather, these exemplary aspects are provided so that this disclosure will be thorough and complete and will fully convey the concept of the disclosure to those skilled in the art, and the present disclosure will only be defined by the appended claims. Throughout the specification, the same reference numerals refer to the same components.

When a component is described as “connected to” or “coupled to” another component, it may refer to a direct connection or coupling with the other component, or to a case where another component is interposed therebetween. Meanwhile, when a component is referred to as “directly connected to” or “directly coupled to” another component, it indicates that there is no other component interposed therebetween. The expression “and/or” is taken to include each of the mentioned items and any combination of one or more.

The terminology used in this specification is for the purpose of describing aspects, and is not intended to limit the present disclosure. In this specification, the singular form includes the plural form unless otherwise specified in the phrase. The “comprises” and/or “comprising” used in the specification do not preclude the presence or addition of one or more other components, steps, operations, and/or devices mentioned.

Although the terms “first”, “second”, and the like are used for describing various components, these components are not confined by these terms. These terms are merely used for distinguishing one component from the other components.

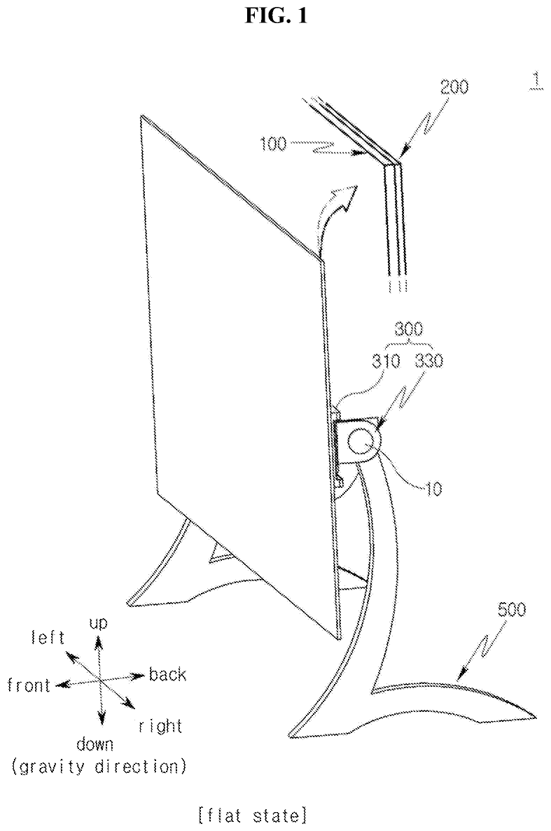

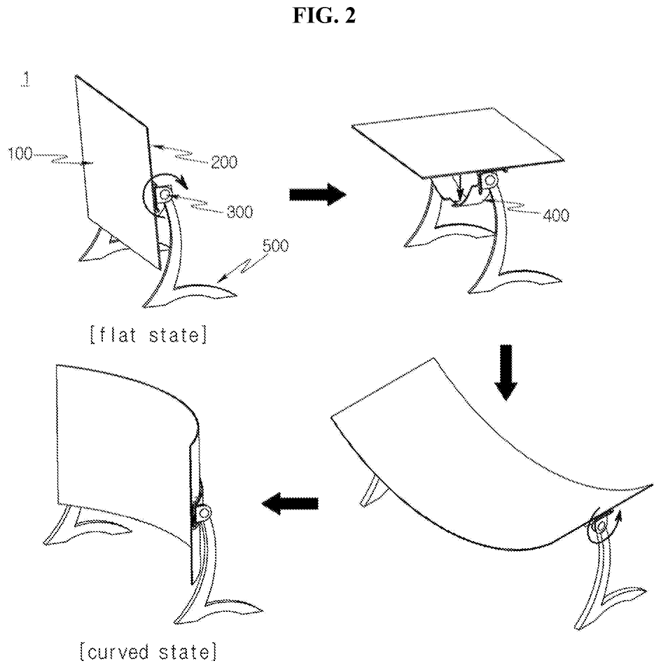

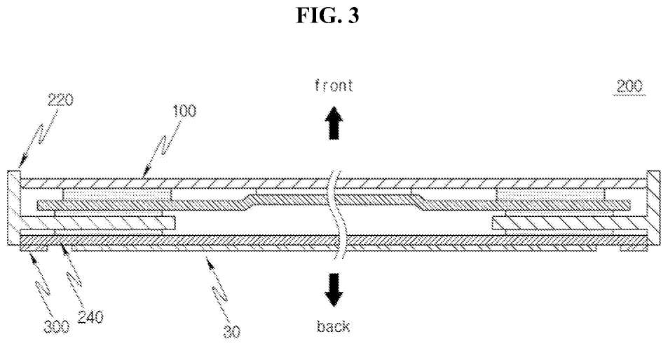

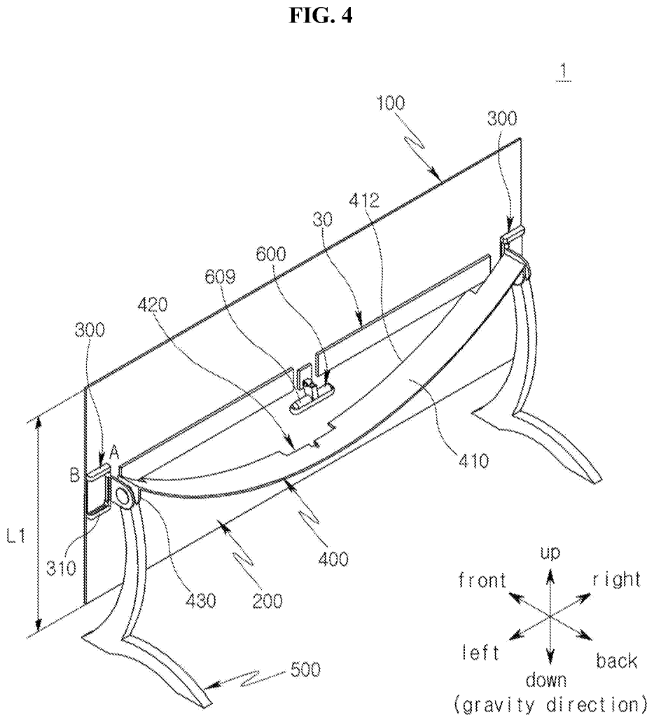

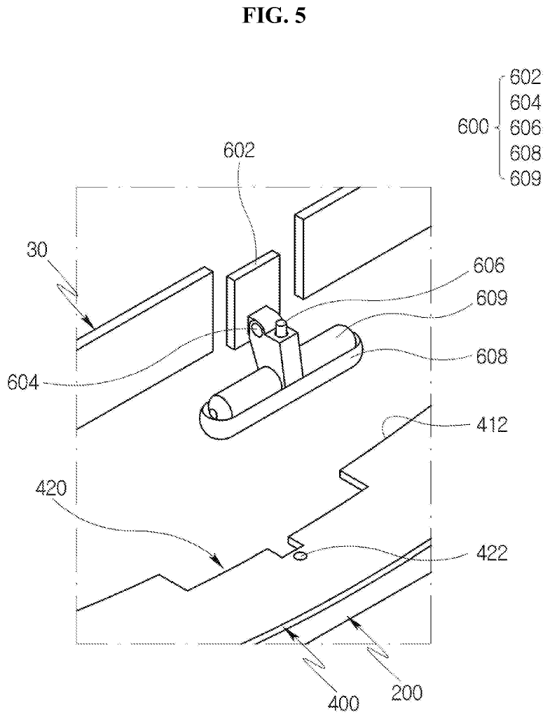

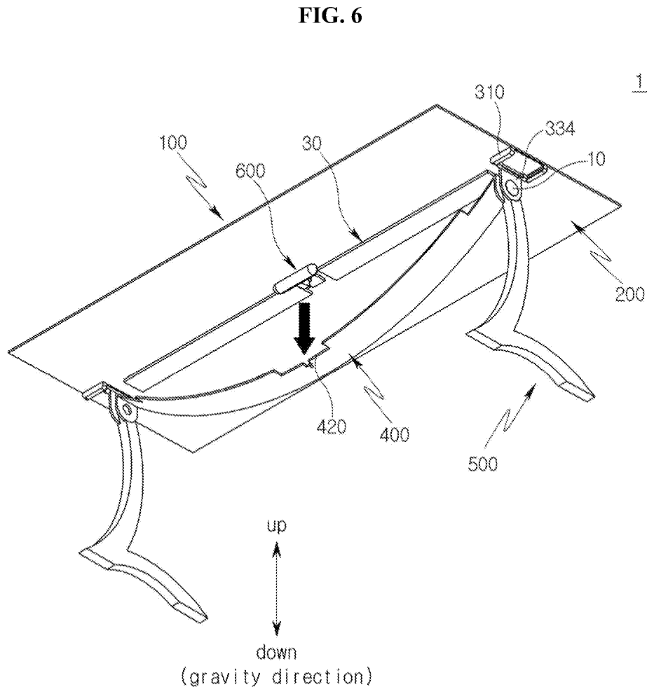

A description is made of the display apparatus according to an aspect of the present disclosure. FIG. 1 is a perspective view of a display apparatus in a flat state according to an aspect, FIG. 2 is a perspective view of a display apparatus switching from a flat state to a curved state according to an aspect, FIG. 3 is a cross-sectional view illustrating an assembled state of a display panel and a back cover according to an aspect, FIG. 4 is a rear perspective view of FIG. 1, FIG. 5 is a partial perspective view of a handle unit and a curved bar according to an aspect, and FIG. 6 is a perspective view of a display apparatus in the state of being rotated to be horizontal for switching from a flat state to a curved state.

With reference to accompanying FIG. 1 to FIG. 6, the display apparatus 1 according to an aspect may be used in such a way as a user intending to switch the display panel 100 from a flat state to a curved state rotates the display panel, in the arrow direction, to be horizontal with respect to the ground as shown in FIG. 2 such that the weight center of the display panel 100 faces the gravity direction, inducing the display panel 100 to bend toward the curved bar 400 having a predetermined curvature for convenient use in the curved state. In this case, the user may easily switch to the curved state without moving from the front to the back of the display apparatus 1. The display apparatus 1 may be switched to a flat state from the curved state for use, and the description thereof will be made later.

For reference, the flat state means that the display panel 100 is erected vertically with respect to the gravity direction, and the curved state means that the display panel 100 is bent with a predetermined curvature toward the front while being erected with respect to the gravity direction. The curved bar 40 may be made of steel or a similar material to be combined with a magnet 30 as described later.

In addition, to switch the display panel 100 from the curved state to the flat state by the user, the display panel 100 is rotated horizontally by the user using the connecting member 10, which is coupled to the tilting unit 300 and serves as a rotation axis for the display panel 100.

And when the user releases the locked state of the handle unit 600 fixed to the curved bar 400 and rotates the display panel 100 to a vertical position, the display panel 100 is switched to the flat state by the inherent elasticity of the display panel 100.

In this aspect, the display panel 100 uses a flexible display, as an example, a bendable display with organic light-emitting materials may be used. The bendable display, using an organic light-emitting diode (OLED) as an example, may be curved or bent with a certain degree of elasticity, allowing users to conveniently switch the display between a flat state and a curved state while in use.

To this end, the display apparatus 1 according to this aspect includes a display panel 100, a tilting unit 300, a curved bar 400, and a support unit 500.

The display panel 100 may be bent or curved with a certain degree of elasticity, and its edges and back surface are covered by the back cover 200.

For example, the back cover 200 includes a first cover portion 220 surrounding the edges of the display panel 100, in the state where the display panel 100 is installed on the front side, and a second cover portion 240 provided on the back surface of the display panel 100.

The tilting unit 300 is positioned at the left and right ends on the back surface of the back cover 200 to serve to switch the display panel 100 between a flat state and a curved state by using the connecting member 10 as a rotation axis and to allow movement of the curved bar 400 and the support unit 500, and detailed description thereof is made later.

Furthermore, the curved bar 400 extends with a certain curvature on the back surface of the back cover 200 and is coupled with the tilting unit 300, and the support unit 500 is coupled with the tilting unit 300 to support the display panel 100.

Prior to a detailed description, it may be briefly explained that the tilting units 300 are located at the left and right ends on the back of the back cover 200. In addition, the support units 500 are respectively coupled with the tilting units 300 located on the left and right sides, and the curved bar 400 is coupled to the support units 500 in a coaxial manner, allowing rotation between the tilted units 300 spaced apart from each other.

The curved bar 400 extends with the same curvature on both the left and right sides from the center of its back surface allowing the display panel 100 to tightly contact the curved bar 400 and maintain the consistent curvature when switched to the curved state. In the case where the curved bar 400 maintains the same curvature as described above, when the user switches the display panel 100 to the curved state and views the screen from the front, the curvature may be consistently maintained at the center, left, and right positions, allowing distortion-free viewing.

As a result, looking at the display panel 100 may enhance user satisfaction and trust in the product.

The back cover 200 is equipped with a magnet 30 that attaches to the curved bar 400 by magnetic force when the display panel 100 is switched from the flat state to the curved state. The magnet 30 is designed to have a magnetic force that makes it easy to attach to and detach from the curved bar 400, and ease of attachment to and detachment from the curved bar 400 during the process of switching from a flat state to a curved state or from a curved state to a flat state may improve user convenience.

As an example, the magnet 30 is arranged on both sides, spaced apart from each other, with the center of the back cover 200 as a reference. For reference, the shape, length, and thickness of the magnet 30 may vary and are not necessarily limited to those shown in the drawings.

As an example, the magnet 30 is located between the tilting parts 300 positioned at the left and right ends of the back cover 200. The magnet 30 is located at the aforementioned position to maintain a stable horizontal state when attached to the curved bar 400 by the magnetic force, as the weight center of the display panel 100 moves towards the direction of gravity when switching from a flat state to a curved state.

For example, when the magnet 30 is positioned at the top or bottom of the back cover 200 rather than the center of the back surface, the position of the curved bar 400 may also be changed, making it difficult to maintain a horizontal position when the display panel 100 is switched to the curved state, so it may be desirable to position the magnet 30 at the center of the back surface as mentioned above.

The back cover 200 according to this aspect includes a handle unit 600 (see FIG. 3 to FIG. 6) that is selectively engaged with the curved bar 400 when the display panel 100 is switched between the flat and curved states.

The handle unit 600 is positioned between the spaced magnets 30.

The handle unit 600 is used when the user switches the display panel 100 from the flat state to the curved state or from the curved state to the flat state.

As an example, the handle unit 600 may be equipped with a weight member 609 of a predetermined weight and be installed at the center of the back surface of the back cover 200. The handle unit 600 may be formed in the shape of ⊥ to allow the user to grip it with their hand but may also be possible to be changed to a different shape.

The handle unit 600 is equipped with a coupling hinge 604 allowing vertical rotation with respect to a fixed member 602 mounted on the back cover 200 and is held by a holding portion 420 formed on the curved bar 400 to maintain a stable coupling state when the display panel 100 is switched to the curved state.

A fixing pin 606 is provided on the handle unit 600 to maintain a fixed state selectively by coupling to the curved bar 400 while being held by the holding portion 420 and maintained in a holding state.

The fixing pin 606 may maintain a stable coupling state between the handle unit 600 and the curved bar 400 by being inserted into an open insertion hole 422 adjacent to the holding portion 420.

The handle unit 600 is comprised of a handle cover 608 made of plastic, as an example, which forms the overall exterior and contains, inside thereof, a weight member 609 exerting weight in the direction of gravity.

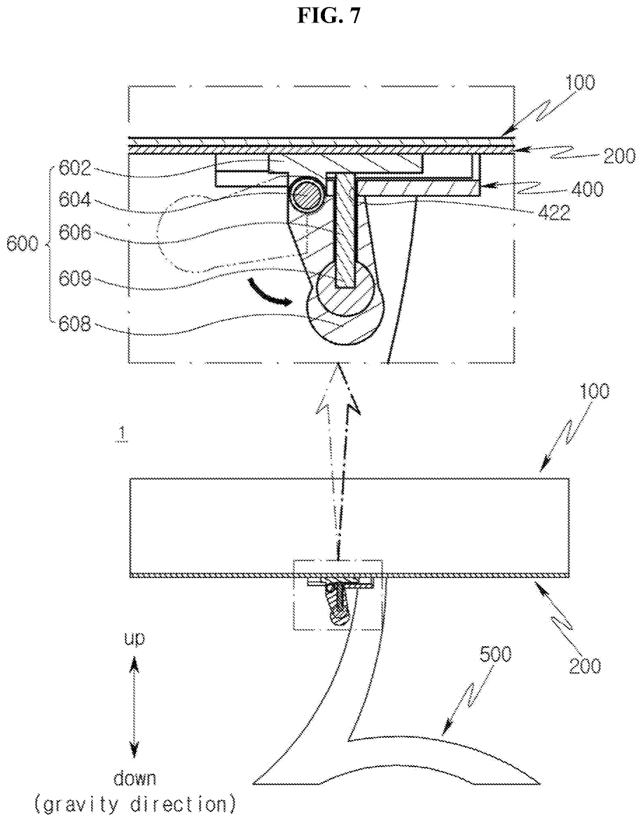

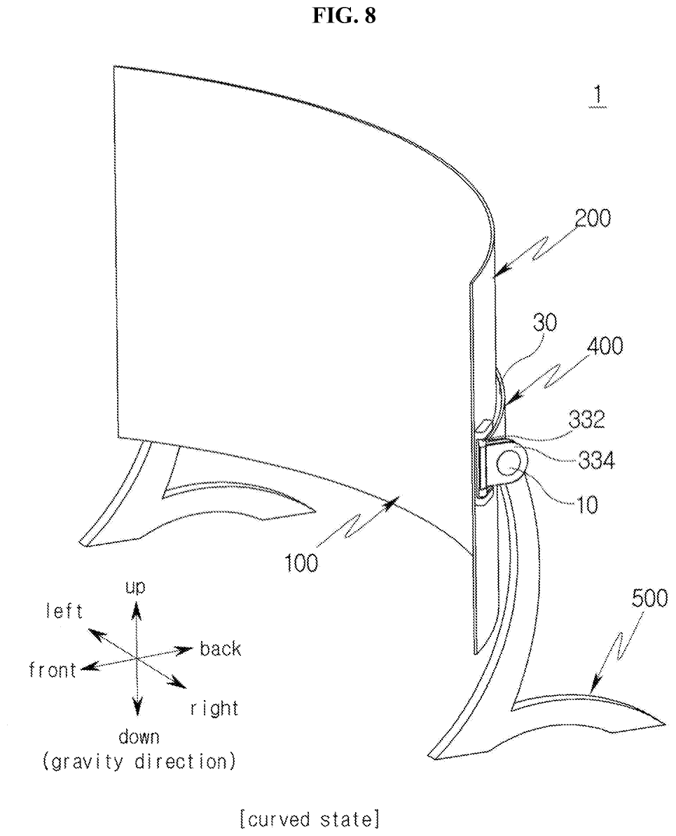

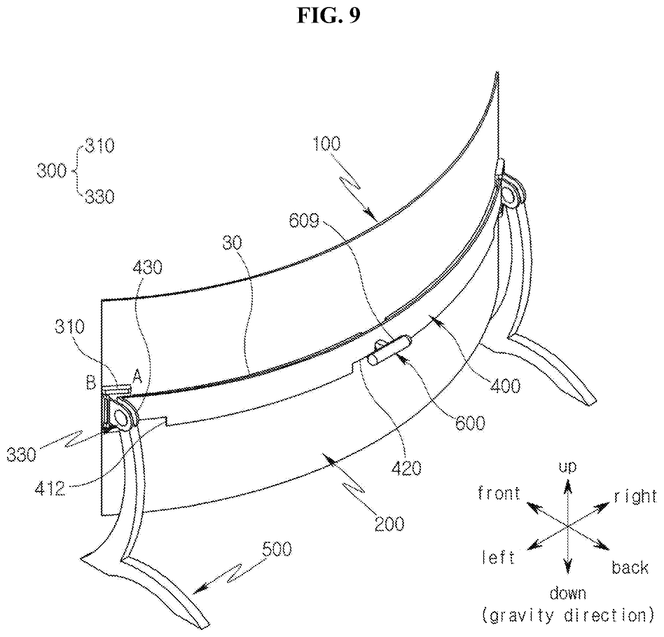

With reference to FIG. 2 or FIGS. 6 to 9, when the display panel 100 is rotated to be horizontal with respect to the tilting unit 300 as a reference, the center of gravity moves in the direction of gravity due to the weight of the display panel itself and the weight of the handle unit 600. Here, “to be horizontal” refers to the state where the display panel 100 in the flat state is rotated 90 degrees backward with respect to the tilting unit 300 as a reference.

As the flexible display is used in the display panel 100, when it is rotated to be horizontal, the center of gravity moves towards the direction of the arrow (gravity direction) in the drawing due to its own weight.

In this aspect, when the display panel 100 is switched to a curved state, the center of gravity is made to face the direction of gravity, which induces the display panel 100 to bend toward the curved bar 400 due to its weight, allowing the user to conveniently switch the display panel to the curved state from the front without moving to the back of the display panel.

The handle unit 600 is equipped with a weight member 609 of a predetermined weight, which adds to the weight of the display panel 100 when the display panel 100 is rotated to be horizontal, causing the display panel 100 to bend towards the arrow direction (i.e., the direction of gravity).

When the display panel 100 is bent after being rotated to be horizontal with respect to the tilting unit 300 as a reference, the magnet 30 is attached to one side of the curved bar 400 by magnetism, resulting in switching to the curved state.

The magnet 30 serves to maintain the stable attachment of the display panel 100 to the curved bar 400, ensuring that the curved state is reliably maintained even when the display panel 100 is rotated to be vertical by the tilting unit 300 after being switched to the curved state by the magnet 30.

In particular, when the display panel 100 is switched to the curved state, the handle unit 600 is held by the hold portion 420, and the aforementioned fixing pin 606 is inserted into the insertion hole 422, allowing the bent state of the display panel 100 to be safely maintained. Therefore, it is possible to stably protect the high-priced display panel 100.

Particularly, when the display panel 100 needs to be switched to the curved state, the user may switch the display panel 100 to the curved state conveniently from the front without moving to the back of the display panel 100.

This aspect allows the user to switch the display panel 100 from the curved state to the flat state from the front of the display apparatus 1 in such a way as to rotate the display panel 100, which is in the curved state with a predetermined curvature toward the front, to be horizontal, release the fixed state of the handle unit 600 from the holding portion 420, and rotate the display panel 100 to be vertical and switched to the flat state by the self-restoring force of the display panel 100.

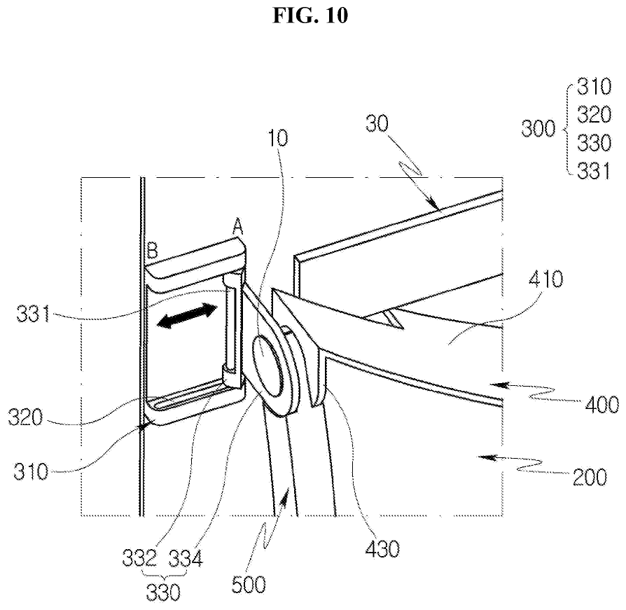

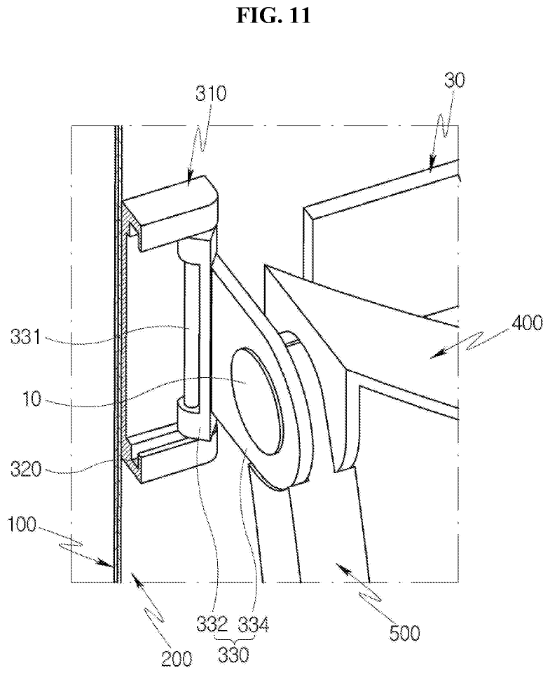

With reference to FIG. 4 or FIGS. 10 to 12, the tilting unit 300 according to this aspect is positioned at the center of the overall vertical length L1 when viewed from the back of the back cover 200. The tilting unit 300 is positioned at that location to stably maintain the horizontal position of the display panel 100 without the center of gravity being eccentric to the front or rear of the display panel 100 when the display panel 100 is rotated to be horizontal and switched from the flat state to the curved state.

When the tilting unit 300 is positioned at that location, the center of gravity of the display panel 100 may be maintained at a constant position when the display panel 100 is rotated to be horizontal or vertical, and the rotation may always be constant without the center of gravity being concentrated on either the upper or lower part of the display panel 100.

The tilting unit 300 includes a tilting unit body 310 that forms the overall appearance, grooves 320 formed on the inner upper surface and inner lower surface of the tilting unit body 310, facing each other in a predetermined direction with a predetermined depth and length, and a tilting arm 330 connected at one end thereof to a sliding pin 331, which is inserted at both ends thereof into the grooves 320, in a rotatable manner and extends toward the rear of the tilting unit 300 at the other end thereof.

The tilting unit 300 is coupled with the curved bar 400 and the support unit 500 via the connecting member 10 in a rotatable manner. The connecting member 10 may be provided in the form of a bolt or rivet to ensure stable rotation of the curved bar 400 and the support unit 500, and may be variously modified without being necessarily limited to a specific form.

The tilting unit body 310 is formed in the shape of a plate, and the grooves 320 are arranged facing each other with a vertical distance on the inner upper and lower surfaces of the tilting unit body 310 when viewed from the rear of the display panel 100 towards the tilting unit 300.

The grooves 320 are formed with a predetermined depth ensuring insertion of the upper and lower ends of the sliding pin 331 in a movable manner.

The grooves 320 are formed horizontally, when viewed from the rear of the display panel 100, allowing the tilting arm 330 connected to the sliding pin 331 to move along the grooves 320.

The tilting arm 330 includes a first tilting arm 332 rounded toward the inside of the tilting unit body 310 and connected to the sliding pin 331 at both ends thereof in the axial direction in an inserted manner, and a second tilting arm 334 extending from the first tilting arm 332 toward the rear of the tilting unit body 310 and hinged to the curved bar 400 and the support unit 500.

The first tilting arm 332 and the second tilting arm 334 are integrally formed, and the first tilting arm 332 may be rotated on the sliding pin 331 as the pivot, while the second tilting arm 334 is coupled to the curved bar 400 and the support unit 500 via the connecting member 10.

As an example, when the display panel 100 is in the flat state, the sliding pin 331 is located at position A, while the curved bar 400 and the support unit 500 remain in connection with the sliding pin 331 located at position A.

In addition, when the display panel 100 is switched to the curved state, the sliding pin 331 moves along the grooves 320 towards both sides of the display panel 100 and is located at position B, while the curved bar 400 and the support unit 500 remain in connection with the sliding pin 331 located at position B.

As such, the curved bar 400 and the support unit 500 move together in conjunction with the operation of the connecting member.

The first tilting arm 332 is formed with a rounded shape towards the inside of the tilting unit body 310 to avoid direct contact with the opposing tilting unit body 310, preventing physical friction when it moves to position A or B. This structure ensures that the first tilting arm 332 may rotate without interruption at specific positions when the tilting arm 330 is in operation.

The second tilting arm 334 is attached externally with reference to the spaced apart support units 500, while the curved bar 400 is attached internally. The connecting members 10 are respectively attached from both sides of the support unit 500 as a reference.

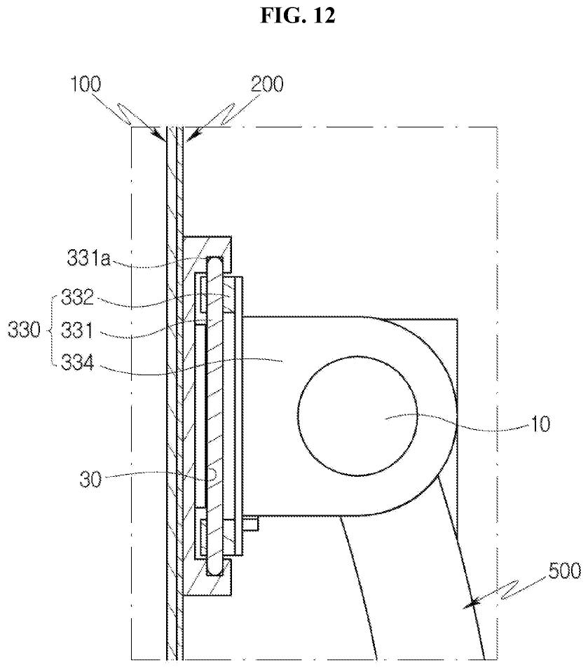

With reference to FIG. 12, the sliding pin 331 includes a round portion 331a formed at the upper and lower ends thereof according to this aspect. The round portions 331a are designed to minimize wear and frictional force caused by the friction generated when the sliding pin 331 moves back and forth along the groove 320. This ensures stable operation even when the display panel 100 is rotated multiple times.

With reference to FIGS. 4 and 5 or FIG. 9, the curved bar 400 according to this aspect includes a curved bar body 410 that forms the overall appearance, a holding portion 420 formed at the center of the curved bar body 410 to maintain the attachment of the handle unit 600, and a third tilting arm 430 formed facing the tilting unit 300 at the extended left and right ends of the curved bar body 410.

The curved bar body 410 extends with a certain curvature towards the display panel 100 as shown in the drawing. The curved bar body 410 may be extended with a predetermined thickness, width, and length, and may be changed in various manners without being limited to the shape and length shown in the drawings.

The third tilting arm 430 is located at the left and right ends of the curved bar body 410 and is coupled coaxially with the second tilting arm 334 for rotational movement on the connecting member 10.

The third tilting arm 430 is coupled with the second tilting arm 334 and the support unit 500, allowing for rotation and movement depending on the rotation of the display panel 100.

The holding portion 420 is formed at the center of the curved bar body 410 in the way of being curved inwardly to allow insertion of the handle unit 600. The holding portion 420 may be formed in other shapes different from the one shown in the drawing for selective fixation of the handle unit 600 without being limited in shape.

The curved bar body 410 has a supporting portion 412 formed integrally therewith to support the back cover 200 when the display panel 100 is in the flat state.

The supporting portion 412 may prevent the occurrence of plastic deformation of a control module equipped inside the display panel 100, by being tightly attached to the back surface of the back cover 200 to support it while the display panel 100, which is frequently transformed between the curved state and the flat state, is switched to the flat state.

The supporting portion 412 is arranged in a symmetrical form with respect to the holding portion 420 to support the back cover 200 in a balanced manner without the supporting force being concentrated at a specific position.

The support unit 500 according to this aspect may support the display panel 100 stably without increasing weight compared to conventional support units and facilitate movement of the display apparatus 1 by reducing its overall weight.

A description is made of the display apparatus according to another aspect of the present disclosure with reference to accompanying drawings.

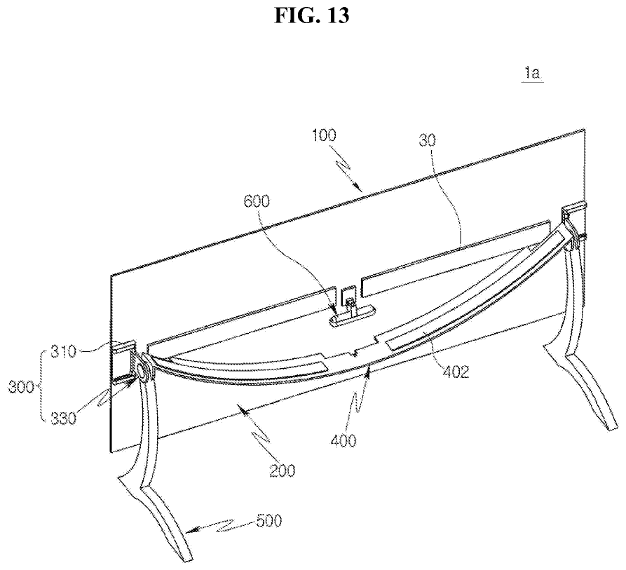

With reference to FIG. 13, the display apparatus 1a according to an aspect may be bent or curved with a certain amount of elasticity and includes a display panel 100 to which a back cover 200 is attached on the back surface, a magnet 30 provided on the back surface of the back cover 200, a tilting unit 300 located at the left and right ends of the back cover 200 and capable of switching the display panel 100 between a flat state and a curved state, a curved bar 400 coupled with the tilting unit 300 in an extended manner with a predetermined curvature above the back surface of the back cover 200, an auxiliary magnet 402 provided on one surface of the curved bar 400 and selectively attached to or detached from the magnet 30, and a support unit 500 coupled to the tilting unit 300 to support the display panel 100.

In this aspect, an auxiliary magnet 402 is provided on the curved bar 400 to improve attachment stability when the magnet 30 is attached to or detached from the curved bar 400.

The auxiliary magnet 402 may be designed in a plate shape, as shown in the drawing, or various modified into other shapes without being limited to any specific shape.

The auxiliary magnet 402 may maintain a weaker magnetic force than the magnet 30 to reduce the difficulty of detachment while enhancing attachment stability, leading to stable use of the display panel 100.

The curved bar 400 is extended on both left and right sides with equal curvature with respect to the center of the back surface of the curved bar 400, and the auxiliary magnet 402 is configured to have the opposite polarity to the magnet 30, ensuring stable attachment performance.

The tilting unit 300 includes a tilting unit body 310 and a tilting arm 330 as described in the prior aspect, and other components are similar to those described in the prior aspect and thus detailed descriptions thereof are omitted.

Although the description has been made with example aspects of the present disclosure, those skilled in the art will appreciate that various modifications and changes, such as addition, alteration, and deletion of components, may be made to the present disclosure without departing from the spirit and scope of the disclosure as set forth in the appended claims, and such modifications and changes are also included within the scope of the disclosure.

It will be apparent to those skilled in the art that various modifications and variations can be made in the display apparatus of the present disclosure without departing from the spirit or scope of the aspects. Thus, it is intended that the present disclosure covers the modifications and variations of the aspects provided they come within the scope of the appended claims and their equivalents.

What is claimed is:

1. A display apparatus comprising:
a display panel including a back cover attached to a back surface thereof and configured to be bent or curved with a predetermined amount of elasticity;
a tilting unit positioned at left and right ends of the back surface of the back cover, allowing the display panel to switch between a flat state and a curved state;
a curved bar extended over the back surface of the back cover with a predetermined curvature and coupled with the tilting unit; and
a support unit connected to the tilting unit to support the display panel.

2. The display apparatus of claim 1, wherein the curved bar extends on both sides with a same curvature with respect to a center of a back surface of the curved bar.

3. The display apparatus of claim 1, wherein the back cover is provided with a magnet inducing, in response to the display panel switching from the flat state to the curved state, an attachment of the curved bar by magnetic force.

4. The display apparatus of claim 3, wherein the magnet is arranged on the left and right sides of the back surface of the back cover centered on the middle of the back surface.

5. The display apparatus of claim 4, wherein the back cover is provided with a handle unit positioned at the center of the back surface of the back cover being selectively engaged with the curved bar in response to the display panel being switched from the flat state to the curved state.

6. The display apparatus of claim 5, wherein the handle unit comprises a weight member of a predetermined weight.

7. The display apparatus of claim 5, wherein the display panel has the center of gravity moving in the direction of gravity, in response to the display panel rotating to be horizontal with respect to the tilting unit, due to the weight of the display panel and the weight of the handle unit.

8. The display apparatus of claim 5, wherein the display panel is configured to bend in the direction of the gravity, in response to the display panel rotating to be horizontal with respective to the tilting unit, to cause the magnet to attach to one surface of the curved bar, thereby being switched to the curved state.

9. The display apparatus of claim 1, wherein the tilting unit is position at the center of the total vertical length of the back cover when viewed from the rear.

10. The display apparatus of claim 1, wherein the tilting unit comprises:
a tilting unit body forming the overall appearance;
a groove formed on the inner upper surface and inner lower surface of the tilting unit body, facing each other and extending in a predetermined depth and length in one direction; and
a tilting arm connected at one end thereof to a sliding pin, which is inserted at both ends thereof into the groove, in a rotatable manner and extends toward the rear of the tilting unit at the other end.

11. The display apparatus of claim 10, wherein the sliding pin comprises a round portion at the upper and lower ends thereof.

12. The display apparatus of claim 10, wherein the tilting arm comprises:
a first tilting arm rounded toward the inside of the tilting unit body and connected to the sliding pin at both ends thereof in the axial direction in an inserted manner; and
a second tilting arm extending from the first tilting arm toward the rear of the tilting unit body and hinged to the curved bar and the support unit.

13. The display apparatus of claim 5, wherein the curved bar comprises:
a curved bar body forming the overall appearance;
a holding portion formed at the center of the curved bar body to maintain the attachment of the handle unit; and
a third tilting arm formed facing the tilting unit at the extended left and right ends of the curved bar body.

14. The display apparatus of claim 13, wherein the curved bar body comprises a supporting portion formed integrally therewith to support the back cover in response to the display panel being in the flat state.

15. The display apparatus of claim 14, wherein the supporting portion is arranged in a symmetrical form with respect to the hording portion.

16. The display apparatus of claim 1, wherein the support unit moves together with the tilting unit when the display panel is switched between the flat state and the curved state.

17. A display apparatus comprising:
a display panel including a back cover attached to the back surface thereof and configured to be bent or curved with a predetermined amount of elasticity;
a magnet provided on the back surface of the back cover;
a tilting unit positioned at a left and right ends of the back surface of the back cover, allowing the display panel to switch between a flat state and a curved state;
a curved bar extended over the back surface of the back cover with a predetermined curvature and coupled with the tilting unit;
an auxiliary magnet provided on one side of the curved bar to be selectively attached to or detached from the magnet; and
a support unit connected to the tilting unit to support the display panel.

18. The display apparatus of claim 17, wherein the curved bar extends on both sides with the same curvature with respect to a center of the back surface of the curved bar, and the auxiliary magnet has the opposite polarity to the magnet.
